(19) United States
(12) Patent Application Publication
(10) Pub. No.: US 2015/0077919 A1
(43) Pub. Date: Mar. 19, 2015

(54) TRANSMISSION LINE WITH DATA STORAGE FUNCTION

(71) Applicant: Power Quotient International Co., Ltd., New Taipei City (TW)

(72) Inventors: Chung Ying Chang, New Taipei City (TW); Hung Chi Tung, New Taipei City (TW); Hsuan Chi Huang, New Taipei City (TW); Shu Chin Liang, New Taipei City (TW); Tzu Ju Huang, New Taipei City (TW); Chia Hsin Tsai, New Taipei City (TW); Tung Ming Chang, New Taipei City (TW)

(73) Assignee: Power Quotient International Co., Ltd., New Taipei City (TW)

(21) Appl. No.: 14/070,621

(22) Filed: Nov. 4, 2013

(30) Foreign Application Priority Data
Sep. 18, 2013 (TW) 102217866

(51) Int. Cl. G11C 5/04

(52) U.S. Cl. CPC G11C 5/04
USPC 361/679.31

(57) ABSTRACT

A transmission line with both data storage function portable structure thereof includes a cable, a memory module, a Micro USB connector, a cover, a housing and a shell. The memory module and the Micro USB connector are connected to two opposite ends of the cable. The cover covers over the memory module. The housing has a front wall, a rear wall and two side walls which corporately define a receiving chamber. A partition is defined at the center of the receiving chamber and divides the receiving chamber into a first receiving cavity and a second receiving cavity. The memory module and the Micro USB connector are respectively located in the first and second receiving cavities of the housing. The shell encloses the housing.

### BACKGROUND OF THE INVENTION

1. Field of the Invention

The present invention relates to a transmission line, and more particularly to a transmission line with data storage function.

2. The Related Art

Nowadays, with the progress of society, various electrical equipments have become indispensable tools in people's daily life. People use a transmission line connected to power and electrical equipment for charging. Sometimes, people also use a transmission line to transfer data between a mobile device and a computer. Therefore, transmission line is widely used in people's daily life for such electrical equipments.

However, when a mobile device or a computer transfers data to flash disk, it is indispensible for people to use the transmission line to connect the mobile/computer with the flash disk to store the data. It is quite inconvenient for people's use.

### SUMMARY OF THE INVENTION

Accordingly, an object of the present invention is to provide a transmission line with data storage function. The transmission line with data storage function includes a cable, a memory module and a Micro USB (Universal Serial Bus) connector. The memory module and the Micro USB connector connect to two opposite ends of the cable respectively. The memory module includes a memory, a USB connector and a switch. The memory is assembled in the memory module for storing the data transferred by way of the cable. The USB connector and the switch are assembled on the memory module.

Another object of the present invention is to provide a transmission line with both data storage function and portable structure thereof. The transmission line with data storage function and portable structure thereof includes a transmission line, a housing and a shell. The transmission line includes a cable, a memory module and a Micro USB connector. The memory module and the Micro USB connector connect to two opposite ends of the cable respectively. The memory module includes a memory for storing data, a USB connector and a switch for switching the operation status. The memory is assembled in the memory module for storing the data transferred by way of the cable. The USB connector and the switch are assembled on the memory module. The transmission line further includes a cover. The cover covers over the memory module. The housing includes a front wall, a rear wall and two side walls, which corporately define a receiving chamber. The center of the receiving chamber is defined as a partition, for connecting to the centers of the front wall, the rear wall and two side walls, which further divides the receiving chamber into a first receiving cavity above the partition and a second receiving cavity under the partition. The housing further includes a sling. The sling is fixed on the front wall of the housing. The shell has a front plate and a plurality of side plates protruded rearward from the edges of the front plate and connecting to one another. A substantial middle area of the front plate defines a through hole. The memory module is received in the first receiving cavity of the housing and the Micro USB connector is received in the second receiving cavity of the housing. The shell encloses the housing. The sling passes through the through hole and extending out of the front face of the front plate of the shell.

As described above, the transmission line with data storage function includes a memory for storing data and a switch for switching operation status between storage and transmission in the memory module, it makes sure the transmission line with the functions of both data storage and transmission.

### BRIEF DESCRIPTION OF THE DRAWINGS

The present invention will be apparent to those skilled in the art by reading the following description thereof, with reference to the attached drawings, in which:

FIG. 1 is an assembled, perspective view of a transmission line with data storage function and portable structure thereof in accordance with an embodiment of the present invention;

FIG. 2 is an assembled, perspective view of a transmission line with data storage function in accordance with an embodiment of the present invention;

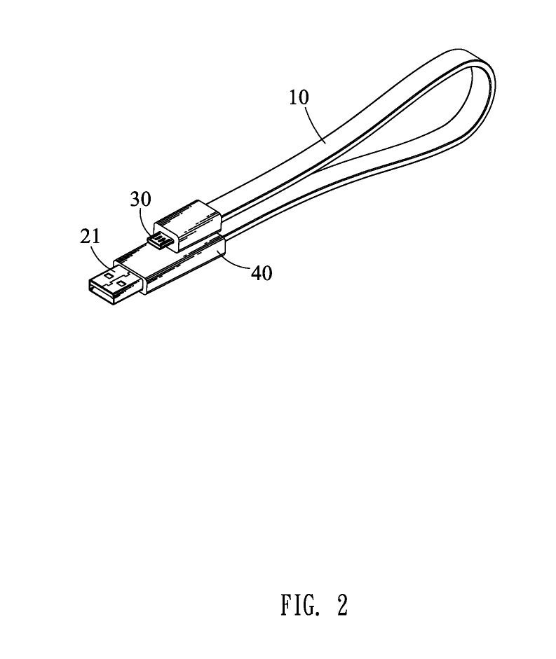

FIG. 3 is an exploded, perspective view of the transmission line with data storage function and portable structure thereof shown in FIG. 1; and

FIG. 4 is a perspective view of the housing of the portable structure of the transmission line with data storage function shown in FIG. 1.

### DETAILED DESCRIPTION OF THE EMBODIMENT

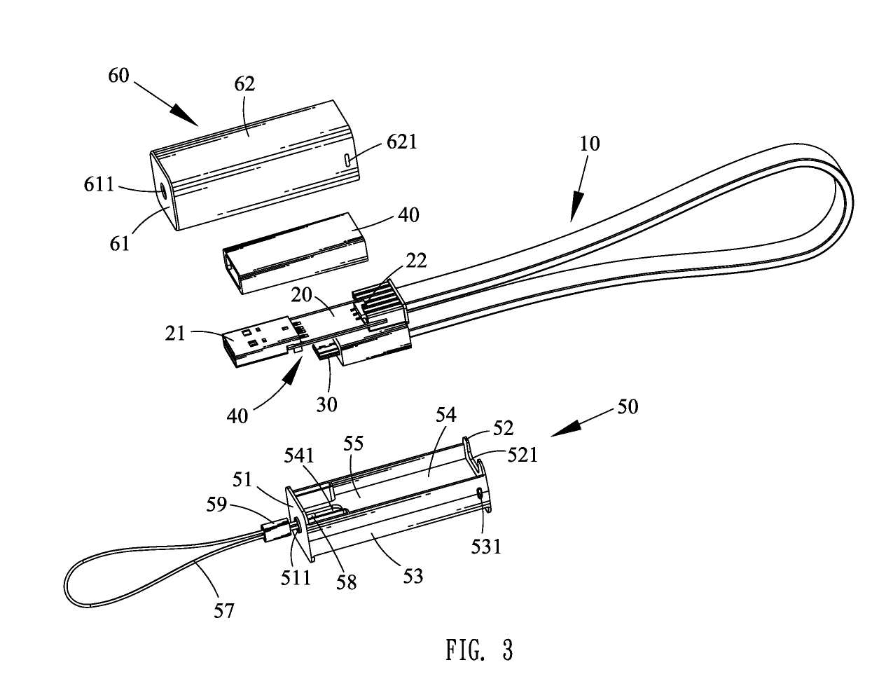

Referring to the drawings in much detail, and first to FIG. 3, an embodiment of the present invention is shown as a transmission line 100. The transmission line includes a cable 10, a memory module 20, a Micro USB connector 30, a cover 40, a housing 50 and a shell 60.

Refer to FIG. 3, the memory module 20 and the Micro USB connector 30 are connected to two opposite ends of the cable 10 respectively. The memory module 20 includes a memory (not labeled), a USB connector 21 and a switch 22. The memory is assembled in the memory module 20 for storing the data transferred by way of the cable 10 and is made by virtue of COB (Chip On Board) process. The USB connector 21 and the switch 22 are assembled on the memory module 20 and are made by virtue of SMT (Surface Mount Technology) process.

The cover 40 covers over the memory module 20, the USB connector 21 of the memory module 20 is extending out of the cover 40.

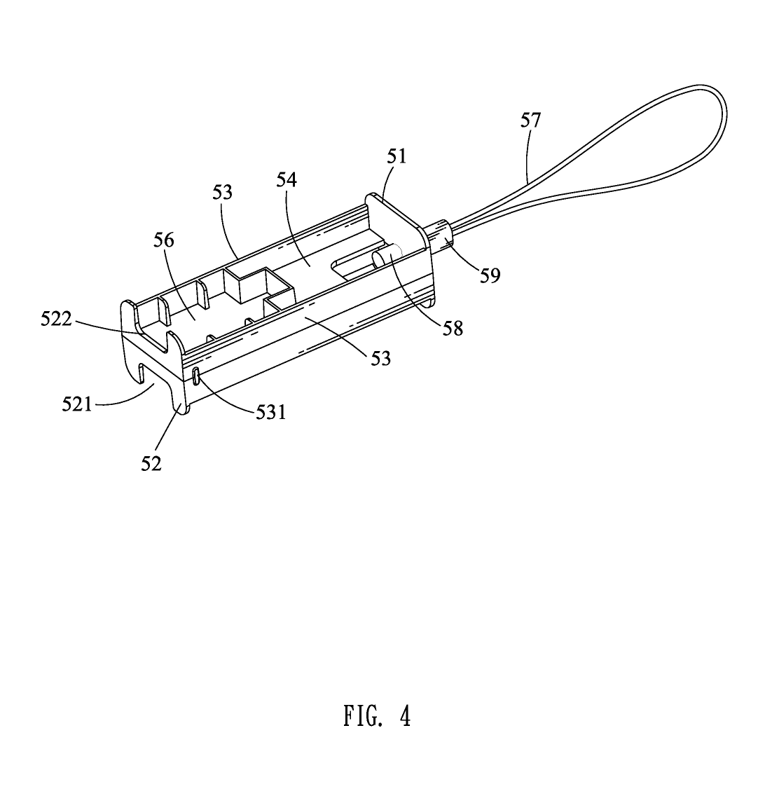

Refer to FIG. 3 and FIG. 4, the housing 50 includes a front wall 51, a rear wall 52 and two side walls 53 which corporately define a receiving chamber (not labeled). A partition 54 is defined at the center of the receiving chamber and connected to the center formed by the front wall 51, the rear wall 52 and two side walls 53. The partition 54 further divides the receiving chamber into a first receiving cavity 55 above the partition 54 and a second receiving cavity 56 under the partition 54. The memory module 20 with cover 40 is located in the first receiving cavity 55 of the housing 50 and the Micro USB connector 30 is located in the second receiving cavity 56 of the housing 50. A middle of a top and a bottom ends of the rear wall 52 are respectively concaved downward to form a first trough 521 and concaved upward to form a second trough 522 respectively corresponding to the first receiving cavity 55 and the second receiving cavity 56 of the housing 50. The end of the cable 10 connected to the memory module 20 is through the first trough 521. The other end of the cable 10 connected to the Micro USB connector 30 is through the second trough 522. A front end of the partition 54 is concaved rearward to form a receiving slot 541 adjacent to the front wall 51 of the housing 50. A substantial middle of the front wall 51 is opened as a fixing hole 511 which penetrating through the front wall 51. Two opposite side walls 53 of the housing 50 defines a pair of positioning lumps 531.

Refer to FIG. 3 and FIG. 4, the housing 50 further including a sling 57 and a fastening plug 58 which is located in the receiving slot 541 and is fastened at two opposite ends of the sling 57, the fastening plug 58 is located in the receiving slot 541 of the housing 50 and the sling 57 passes through the fixing hole 511 of the front wall 51 of the housing 50 and extending out of the front face of the front wall 51.

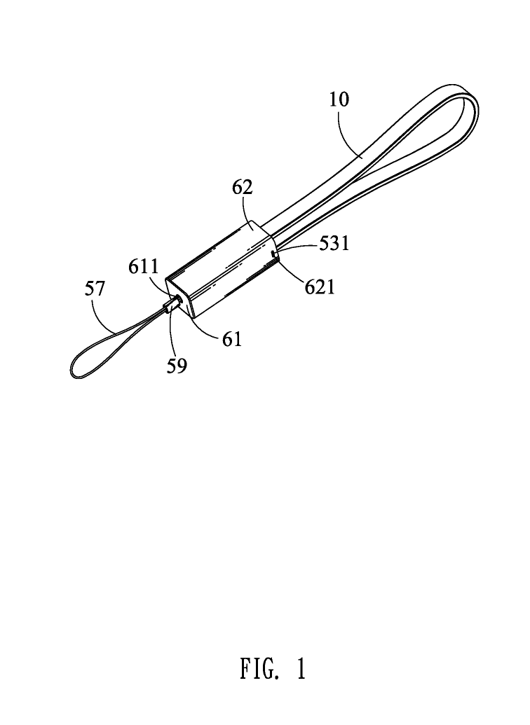

Refer to FIG. 1 and FIG. 3, the shell 60 encloses rearward the housing 50, the shell 60 has a front plate 61 and a plurality of side plates 62 protruded rearward from the edges of the front plate 61 and connected with one another. A substantial middle of the front plate 61 is opened as a through hole 611 corresponding to the fixing hole 511 of the front wall 51 of the housing 50. The sling 57 passes through the through hole 611 and extending out of the front face of the front plate 61 of the shell 60. The housing 50 further including a pipe 59 slideable setting outside the sling 57 and stopped in front of the front plate 61. Two opposite side plates 62 of the shell 60 corresponding to the positioning lumps 531 of the side walls 53 of the housing 50 defines a pair of positioning holes 621. The positioning lumps 531 of the side walls 53 of the housing 50 are located in the positioning holes 621 of the side plates 62 of the shell 60.

As described above, the embodiment of the invention of the transmission line 100 with data storage function including a memory for storing data and a switch for switching the status between storage and transmission in memory module 20, it makes sure the transmission line 100 with the functions of both storage and transmission.

What is claimed is:

1. A transmission line with data storage function, comprising:
a cable;
a memory module connected to one end of the cable, including a memory, a USB connector and a switch, the memory being assembled in the memory module for storing the data transferred by way of the cable, the USB connector and the switch being assembled on the memory module; and
a Micro USB connector connecting to the other end of the cable.

2. The transmission line as claimed in claim 1, wherein the memory module is made by virtue of COB process.

3. The transmission line as claimed in claim 2, wherein the switch is made by virtue of SMT process.

4. The transmission line as claimed in claim 1, wherein the transmission line further including a cover for the memory module, the USB connector of the memory module is extending out of the cover.

5. The transmission line as claimed in claim 4, wherein further comprising:
a housing having a front wall, a rear wall and two side walls which corporately define a receiving chamber, a partition being defined at the center of the receiving chamber and connecting to the center formed by the front wall, the rear wall and two side walls and further dividing the receiving chamber into a first receiving cavity above the partition and a second receiving cavity under the partition;
a sling fixed on the front wall of the housing; and
a shell having a front plate, and a plurality of side plates protruded rearward from the edges of the front plate and connecting with one another, a substantial middle of the front plate being opened as a through hole;
wherein the memory module is located in the first receiving cavity of the housing, the Micro USB connector is located in the second receiving cavity of the housing, the shell enclosing the housing, the sling passing through the through hole and extending out of the front face of the front plate of the shell.

6. The transmission line as claimed in claim 5, wherein a middle of a top and a bottom ends of the rear wall are respectively concaved downward to form a first trough and concaved upward to form a second trough corresponding to the first receiving cavity and the second receiving cavity of the housing, the end of the cable connected to the memory module is through the first trough and the other end of the cable connected to the Micro USB connector is through the second trough.

7. The transmission line as claimed in claim 5, wherein a front end of the partition is concaved rearward to form a receiving slot adjacent to the front wall of the housing, the housing further includes a fastening plug which is located in the receiving slot and is fastened at two opposite ends of the sling.

8. The transmission line as claimed in claim 5, wherein a substantial middle of the front wall is opened as a fixing hole which penetrates through the front wall, the sling passes through the fixing hole of the front wall of the housing and extending out of the front face of the front wall.

9. The transmission line as claimed in claim 5, wherein the housing further includes a pipe slideably set outside the sling and in front of the front plate of the housing.

10. The transmission line as claimed in claim 5, wherein two opposite side walls of the housing protrude outside to form a pair of positioning lumps, two opposite side plates of the shell define a pair of positioning holes for receiving the respective positioning lumps of the side walls of the housing.
